(19) United States
(12) Patent Application Publication
(10) Pub. No.: US 2004/0238924 A1
(43) Pub. Date: Dec. 2, 2004

(54) Semiconductor package

(76) Inventor: Ho Uk Song, Kyoungki-do (KR)

Correspondence Address: LADAS & PARRY LLP, 224 SOUTH MICHIGAN AVENUE, SUITE 1200, CHICAGO, IL, 60604, US

(21) Appl. No.: 10/654,846

(22) Filed: Sep. 4, 2003

(30) Foreign Application Priority Data
May 27, 2003 (KR) 2003-33784

(51) Int. Cl. H01L 23/02

(52) U.S. Cl. 257/678

(57) ABSTRACT

Disclosed is a semiconductor package capable of reducing thickness of the semiconductor package. The semiconductor package has a first semiconductor chip including a plurality of first bonding pads, a second semiconductor chip aligned adjacent to the first semiconductor chip in the same plane and having a plurality of second bonding pads transferring signals identical to signals transferred by the first bonding pads, planar layers formed on the first and second semiconductor chips and having openings for exposing first and second bonding pads transferring the same signals and metal patterns covering the openings to connect the first bonding pads to the second bonding pads transferring signals identical to signals transferred by the first bonding pads. The semiconductor package is fabricated by connecting adjacent semiconductor chips to each other in the same plane, instead of vertically stacking the semiconductor chips, so that thickness of the semiconductor package is reduced.

### BACKGROUND OF THE INVENTION

1. Field of the invention

The present invention relates to a semiconductor package, and more particularly to a semiconductor package capable of reducing the thickness thereof.

2. Description of the Prior Art

In semiconductor industries, packaging techniques for integrated circuits have been continuously developed in order to fabricate small-sized semiconductor devices and to improve reliability of a semiconductor device mounting work. For example, semiconductor packages having a size substantially identical to a size of a semiconductor chip have been developed to satisfy with a requirement for small-sized semiconductor devices. In addition, in order to satisfy with a requirement for the reliable mounting work of the semiconductor devices, various packaging techniques capable of improving mechanical and electrical properties of the semiconductor devices once they have been mounted and capable of improving efficiency for mounting the semiconductor packages have been developed.

As high-performance and small-sized electric/electronic appliances are in demand by consumers, research and development are variously carried out to provide a high-capacity semiconductor module. In order to provide the high-capacity semiconductor module, capacity of a memory chip is increased, that is, the memory chip is highly integrated. The high-integration of the memory chip can be achieved by filling a plurality of cells into a space of a semiconductor chip within the limits of possibility. However, the above-mentioned high-integration of the memory chip requires technologies with high degree of difficulty and large time for development, for example, it requires a minute pattern width. For this reason, a stack technique has been suggested to provide the high-capacity semiconductor module. “Stack” means that at least two semiconductor chips or semiconductor packages are vertically piled up. According to the stack technique, 128M DRAM can be achieved by stacking two 64M DRAMs, and 256M DRAM can be achieved by stacking two 128M DRAMs. In addition, a stack package has advantages that memory capacity is increased, density of mounting components is improved, and a mounting space is effectively used. For this reason, research and development for the stack package have been variously carried out.

FIG. 1 is a sectional view showing a conventional stack package.

As shown in FIG. 1, the conventional stack package includes a top package 10b vertically piled on a bottom package 10a. An outer lead 4b of the top package 10b is electrically connected to an outer lead 4a of the bottom package 10a.

The bottom package 10a includes an inner frame having an inner lead 3a attached to a first semiconductor chip 1a formed at an upper surface there of with a bonding pad 2a. The inner lead 3a is connected to the bonding pad 2a through a metal wire 5. The bottom package 10a is molded by a sealing member 6 in such a manner that the outer lead 4a of the lead frame is protruded from both sides of the sealing member 6. The top package 10b has a structure similar to the structure of the bottom package 10a. In the top package 10b, reference numerals 1b, 2b, 3b, and 4b represent a semiconductor chip, a bonding pad, an inner lead, and outer lead, respectively.

To fabricate the conventional stack package having the above structure, the top and bottom packages 10b and 10a are firstly manufactured. Then, the top package 10b is vertically stacked on the bottom package 10b and the outer lead 4b of the top package 10b is electrically connected to the outer lead 4a of the bottom package 10a.

After that, although it is not illustrated, the stack package is placed on a printed circuit board and a reflow process is carried out to mount the stack package on the printed circuit board.

Instead of the above process, the bottom package can be placed on the printed circuit board by interposing a solder paste therebetween. In this state, the top package is placed on an upper surface of the bottom package by using the solder paste and the reflow process is carried out in order to electrically connect the outer lead of the bottom package to the outer lead of the top package, thereby mounting the stack package on the printed circuit board.

However, the conventional stack package has vertically stacked bottom and top packages, so thickness of the stack package is increased. For this reason, there are limitations to increasing the number of packages to be stacked and the memory capacity.

### SUMMARY OF THE INVENTION

Accordingly, the present invention has been made to solve the above-mentioned problems occurring in the prior art, and an object of the present invention is to provide a semiconductor package capable of reducing thickness thereof.

In order to accomplish this object, there is provided a semiconductor package comprising a first semiconductor chip including a plurality of first bonding pads, a second semiconductor chip aligned adjacent to the first semiconductor chip in the same plane and having a plurality of second bonding pads transferring signals identical to signals transferred by the first bonding pads, planar layers formed on the first and second semiconductor chips and having openings for exposing first and second bonding pads transferring the same signals; and metal patterns covering the openings to connect the first bonding pads to the second bonding pads transferring signals identical to signals transferred by the first bonding pads.

According to the preferred embodiment of the present invention, a seed metal layer is interposed between the planar layer and the metal patterns. In addition, an oxide layer is interposed between the planar layer and the metal patterns so as to release stress applied thereto. The oxide layer includes polyimide-based material.

The seed metal layer has a triple stack-layer structure including Ti—NiV—CU layers.

The metal patterns pass through a scribe line formed between the first and second semiconductor chips in order to electrically connect the first and bonding pads, which transfer the same signals.

According to another embodiment of the present invention, there is provided a semiconductor package comprising a first semiconductor chip including a plurality of first bonding pads, a second semiconductor chip aligned adjacent to the first semiconductor chip in the same plane and having a plurality of second bonding pads transferring signals identical to signals transferred by the first bonding pads, a first planar layer formed on the first and second semiconductor chips and having a first opening for exposing first and second bonding pads transferring the same signals, a first metal pattern covering the first opening, a seed metal layer interposed between the first planar layer and the first metal pattern, a second planar layer formed on the first planar layer including the first metal pattern and having a second opening to expose a part of the first metal pattern, a second metal pattern covering the second opening, and a second seed metal layer interposed between the second planar layer and the second metal pattern.

The second metal pattern is aligned in cross with the first metal pattern in a form of a bridge.

An oxide layer is interposed between the first planar layer and the first metal pattern so as to release stress applied thereto. The oxide layer includes polyimide-based material.

The first and second seed metal layers have a triple stack-layer structure including Ti—NiV—CU layers and the first and second metal patterns include any one selected from the group consisting of Al, Cu, and Ag.

The first and second metal patterns pass through a scribe line formed between the first and second semiconductor chips.

### BRIEF DESCRIPTION OF THE DRAWINGS

The above and other objects, features and advantages of the present invention will be more apparent from the following detailed description taken in conjunction with the accompanying drawings, in which:

FIG. 1 is a sectional view showing a conventional semiconductor package;

FIG. 2 is a plan view of a semiconductor package according to one embodiment of the present invention;

FIG. 3 is a sectional view taken along a line A-B shown in FIG. 2;

FIG. 4 is a view showing cross parts of metal patterns according to one embodiment of the present invention; and

FIG. 5 is a sectional view taken along a line C-D shown in FIG. 4; and

FIG. 6 is a plan view of a wafer used for fabricating a semiconductor package according to one embodiment of the present invention.

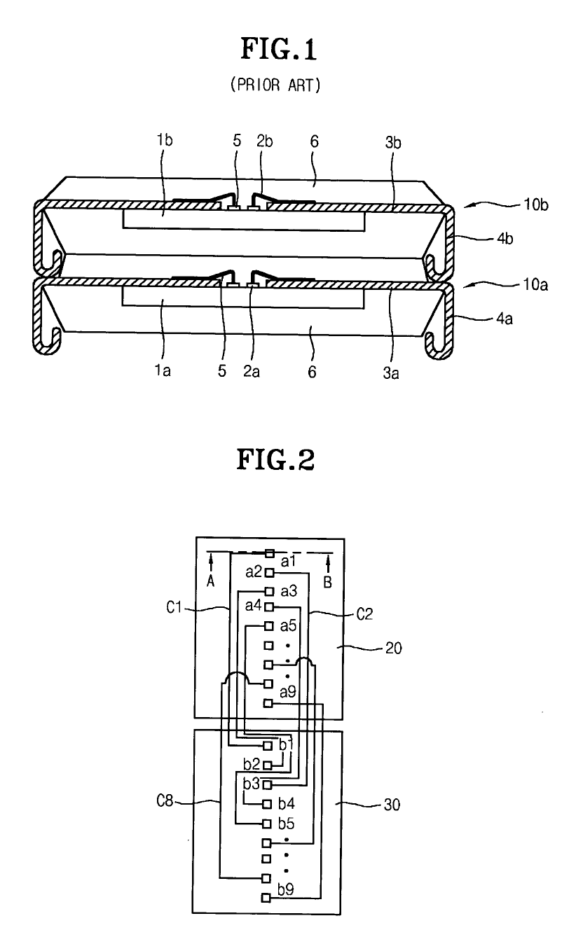

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

A semiconductor package according to the present invention includes first and second semiconductor chips aligned in the same plane in adjacent to each other, in which first and second bonding pads of the first and second semiconductor chips, which transfer the same signals, are connected to each other through metal patterns, so that thickness of the semiconductor package according to the present invention is reduced as compared with thickness of a conventional vertical-stack type semiconductor package.

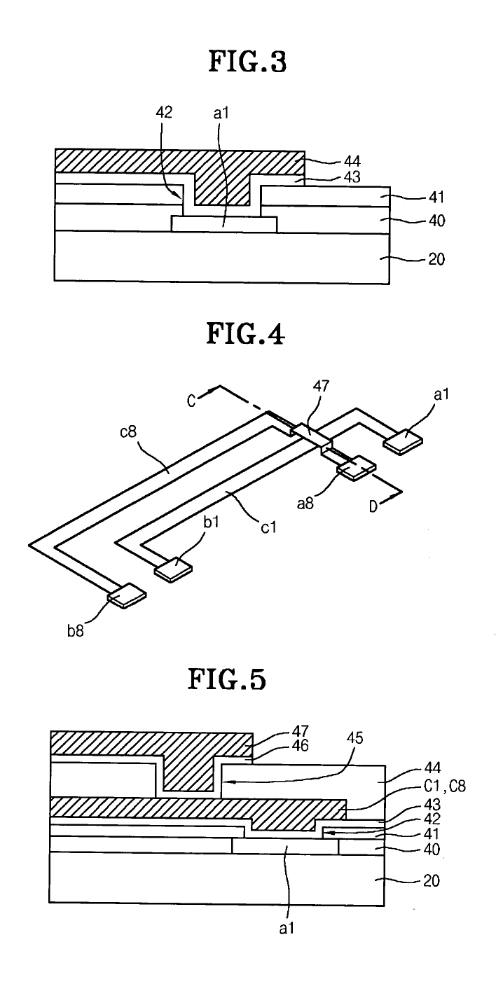

FIGS. 2 and 3 are views for explaining a semiconductor package according to one embodiment of the present invention. FIG. 2 is a plan view of the semiconductor package before a molding process is carried out, and FIG. 3 is a sectional view taken along a line A-B shown in FIG. 2.

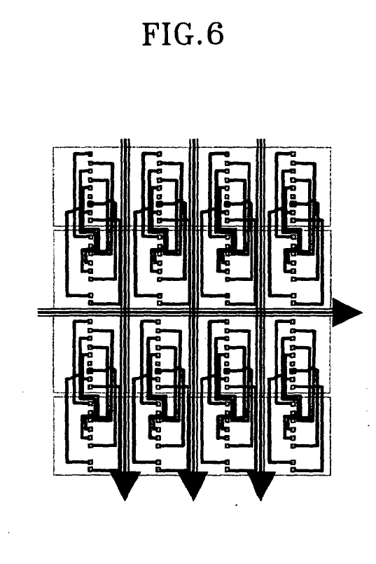

FIG. 4 is a view showing cross parts of metal patterns c1 and c8 according to one embodiment of the present invention, and FIG. 5 is a sectional view taken along a line C-D shown in FIG. 4.

As shown in FIGS. 2 and 3, the semiconductor package of the present invention includes a first semiconductor chip 20 having a plurality of first bonding pads a1 to a9 and a second semiconductor chip 30 having a plurality of second bonding pads b1 to b9, which transfer signals identical to signals transferred by the first bonding pads a1 to a9. The first and second semiconductor chips 20a and 30 are aligned in the same plane.

Hereinafter, the first bonding pads a1 and a8 and the second bonding pads b1 and b8 will be explained as examples for the convenience of description.

A first planar layer 40 is formed on the entire surface of the first and second semiconductor chips 20 and 30. The first planar layer 40 has a first opening 42 for exposing the first bonding pads a1 and a8 and the second bonding pads b1 and b8, which transfer the same signals.

In addition, a first seed metal layer 43 and first metal patterns c1 and c8 are sequentially formed on the first planar layer 40 in order to connect the first bonding pads a1 and a2 to the second bonding pads b1 and b2. An oxide layer 41 is interposed between the first seed metal layer 43 and the first metal patterns c1 and c8 in order to release physical stress applied thereto and to improve adhesive force. The oxide layer 41 is made of polyimide-based material.

In addition, the first seed metal layer 43 has a triple stack-layer structure including Ti—NiV—Cu layers. The first metal patterns c1 and c8 are made by using any one selected from the group consisting of Al, Cu and Ag.

On the other hand, the first metal patterns are not formed between the first bonding pad a7 and the second bonding pad b6 (that is, chip select bonding pads), through which signals for controlling the first and second semiconductor chips are passed, in order to electrically insulate the first bonding pad a7 from the second bonding pad b6.

As shown in FIGS. 4 and 5, a second planar layer 44 is formed on the first metal patterns c1 and c8. The second planar layer 44 has a second opening 45 for exposing a predetermined part of the first metal patterns c1 and c8.

A second seed metal layer 46 and a second metal pattern 47 are sequentially formed on the second planar layer 44 in such a manner that they are connected to the first metal patterns c1 and c8 while covering the second opening 45.

That is, the second metal pattern 47 in the form of a bridge is formed at cross points between first metal patterns c1 and c8.

As the same with the first seed metal layer 43 and the first metal patterns cl and c8, the second seed metal layer 46 has a triple stack-layer structure including Ti—NiV—Cu layers and the second metal pattern 47 is made by using any one selected from the group consisting of Al, Cu and Ag.

In addition, the first and second metal patterns c1, c8 and 47 are aligned in such a manner that they pass through a scribe line area (not shown) formed between the first and second semiconductor chips.

FIG. 6 is a plan view of a wafer used for fabricating the semiconductor package according to the present invention.

As mentioned above, semiconductor chips formed on the wafer are divided into a plurality of semiconductor chips through a sawing process and two semiconductor chips connected to each are subject to a molding process in order to fabricate the semiconductor package. However, according to another embodiment of the present invention as shown in FIG. 6, two semiconductor chips formed on the wafer adjacent to each other are connected to each other as one unit through the metal patterns and the sawing process are carried out with respect to the unit of semiconductor chips. After that, the molding process is carried out with respect to the unit of semiconductor chips, thereby fabricating the semiconductor package. Arrows shown in FIG. 6 represent sawing directions.

According to the present invention, the semiconductor package is fabricated by connecting adjacent semiconductor chips to each other in the same plane, instead of vertically stacking the semiconductor chips, so that the thickness of the semiconductor package can be reduced.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A semiconductor package comprising:
a first semiconductor chip including a plurality of first bonding pads;
a second semiconductor chip aligned adjacent the first semiconductor chip in a common plane and having a plurality of second bonding pads;
first and second planar layers formed substantially parallel to the common plane, wherein the first planar layer is formed on the first and second semiconductor chips and has first openings to expose the first and second bonding pads and further wherein the second planar layer has second openings; and
metal patterns electrically connecting each of the first bonding pads to the predetermined one of the second bonding pads exposed through the first openings to transfer signals between two connected bonding pads,
wherein the metal patterns are preferably formed between the first and second planar layers, and
wherein at least a portion of one metal pattern (which electrically connects a predetermined one of the first bonding pads to another predetermined one of the second bonding pads) is laid on the second planar layer through the second openings to cross over a portion of another metal pattern laid in between the first and second planar layers.

2. The semiconductor package as claimed in claim 1,
wherein a first seed metal layer is interposed between the metal patterns and the first planar layer and
wherein the second seed metal layer is interposed between the portion of metal layer and the second planar layer.

3. The semiconductor package as claimed in claim 1, wherein an oxide layer is interposed between the first planar layer and the metal patterns to relieve stress.

4. The semiconductor package as claimed in claim 3, wherein the oxide layer is made of a polyimide-based material.

5. The semiconductor package as claimed in claim 2, wherein the seed metal layer has a triple lamination including Ti, NiV, and CU layers stacked on each other.

6. The semiconductor package as claimed in claim 1, wherein the metal patterns include any one selected from the group consisting of Al, Cu, and Ag.

7. The semiconductor package as claimed in claim. 1, wherein scribe lines are formed betweeen the first and second semiconductor chips to align the metal patterns.

8-14. (cancelled)
